(19) United States
(12) Patent Application Publication
(10) Pub. No.: US 2025/0324537 A1
(43) Pub. Date: Oct. 16, 2025

(54) Functional module for creating a decentralized automation platform

(71) Applicant: Murrelektronik GmbH, Oppenweiler (DE)

(72) Inventors: Olaf Prein, Lügde-Rischenau (DE); Heiko Feisst, Schlierbach (DE); Tim Roolf, Backnang (DE)

(21) Appl. No.: 19/172,237

(22) Filed: Apr. 7, 2025

(30) Foreign Application Priority Data
Apr. 12, 2024 (DE) 10 2024 110 302.7

(51) Int. Cl. H05K 7/14

(52) U.S. Cl. CPC H05K 7/1475; H05K 7/1482; H05K 7/1484

(57) ABSTRACT

Disclosed herein is a functional module for forming a decentralized automation platform that the functional module is modularly connected to a plurality of further functional modules to provide a plurality of functions for the automation of an industrial plant in a modular manner, having:
an electronic arrangement for providing at least one of the plurality of functions,
a base body with a base body housing in which the electronic arrangement is arranged,
a connection arrangement, arranged on the base body housing and/or is electrically connected to the electronics arrangement to provide an electrical connection for one of the plurality of further functional modules,
   wherein the connection arrangement is designed to provide a main energy flow, an auxiliary energy flow and a data flow between the functional module and the connected further functional module i to operate the automation platform for automation of the industrial plant.

### RELATED APPLICATION(S)

This application claims the benefit of German Application DE, 10 2024 110 302.7 (filed on Apr. 12, 2024), the entirety of which is incorporated by reference herein.

### FIELD OF THE INVENTION

The present invention relates to a functional module for forming a decentralized automation platform, which can be modularly connected to several other functional modules in order to provide modularly expandable functions for the automation of an industrial plant. Furthermore, the invention relates to the automation platform and a method.

### BACKGROUND

It is known from the state of the art that modular automation solutions are used to supply electrical devices in an industrial plant with energy via power lines and to control them via control lines, such as fieldbus lines or IO-Link. Modularity is often achieved by using individual, independent functional modules that can be individually configured and interconnected via a backplane. This has the advantage that the automation solutions can be flexibly adapted to the respective requirements of the industrial plant, thus ensuring a high level of efficiency and cost-effectiveness.

A common problem with conventional solutions is that the assembly of functional modules on an automation platform is time-consuming and error-prone. Furthermore, conventional automation platforms often cannot be adapted flexibly enough to individual requirements, as the combination of functional modules is limited by the design of the backplane. The higher space requirements of known solutions can also be a problem.

It is therefore a task of the present invention to at least partially eliminate the disadvantages described above. In particular, it is a task of the present invention to improve the combination of functional modules to form an automation platform for industrial systems.

### SUMMARY

The subject matter of the invention is a function module, also referred to as functional module, with the features of claim 1, an automation platform with the features of claim 13 and a method with the features of claim 15. Further features and details of the invention are apparent from the respective subclaims, the description and the drawings. Features and details described in connection with the functional module according to the invention naturally also apply in connection with the automation platform according to the invention and the method according to the invention, and vice versa in each case, so that reference is or can always be made to the individual aspects of the invention with respect to the disclosure.

The object of the invention is, in particular, a functional module for forming (creating) a decentralized automation platform.

The automation platform can be formed, for example, by connecting the functional module to further functional modules. In other words, in this automation platform, the functional module can be connected to several further functional modules in a modular fashion. This makes it possible to provide several functions for the automation of an industrial system in a modularly expandable manner. A modular structure of the automation platform can therefore be provided, in which desired functions for automating the industrial system can be added by connecting further function modules, also referred to as further functional modules. The functions can be expanded modularly—“modularity” of the functions here means in particular that the functions can be put together from a selection of functions by selecting and connecting the corresponding functional modules. The functional modules are compatible with each other, but may not be completely identical, as different connection configurations may be provided depending on their individual function.

The functional module and, if applicable, each of the further functional modules may optionally comprise an electronic arrangement for providing at least one of the plurality of functions. In other words, the functions can be performed at least in part by an electronic system, such as, for example, a control or a power supply for electrical devices of the system. Further exemplary functions that can be provided in particular by the functional module and possibly the further functional modules are not exhaustive: monitoring of processes, regulation of temperature, pressure or humidity, data acquisition and processing, communication with other systems, safety monitoring and control, remote control of systems and devices, diagnosis of faults and malfunctions and control of robots.

The functional module and, if applicable, each of the further functional modules can optionally have a base body, also referred to as main body, with a base body housing, also referred to as main body housing, in which the electronic arrangement may be arranged. The electronic arrangement can be arranged in the base body housing during manufacture, for example, by inserting the electronic arrangement with its circuit board into the base body housing and fastening it. The circuit board can be fixed in the base body housing with fastening elements, e.g. by screwing or gluing. Another possibility is that the electronic arrangement is accommodated in a separate housing, which is then inserted into the base body housing.

The functional module, also referred to as functional module, and possibly each of the further functional modules can optionally have a (in particular first) connection arrangement, which is arranged on the basic body housing and/or a housing connected thereto and/or is electrically connected to the electronic arrangement in order to provide an electrical connection for one of the plurality of further functional modules. The connection arrangement can be designed to provide a main energy flow and/or an auxiliary energy flow and/or a data flow (directly) between the functional module and the further functional module connected to it (and/or indirectly via the connected further functional module also to the further functional modules of the automation platform). This enables the automation platform to be operated for the automation of the industrial plant.

The connection arrangement can comprise the following connection elements, in particular in the form of electrical connections:
a main power connection element for providing the main energy flow for the further functional module connected thereto, and/or
an auxiliary power connection element for providing the auxiliary energy flow, in particular with a lower electrical voltage (and/or lower electrical current) than the main energy flow, for the further functional module connected thereto, and/or
a data connection element to provide the data flow for the further functional module connected to it.

The data connection element can be used, for example, to transmit data from a fieldbus and can therefore be designed as a fieldbus connection. The fieldbus is, for example, an industrial data bus that is used to transmit data between different components of an industrial system. The fieldbus enables fast and reliable transmission of data in real time. It is also possible for the data connection element to be used to transmit data from an IO-Link communication system. Accordingly, the data connection element can be capable of receiving and transmitting data from IO-Link-capable sensors and actuators. This enables seamless integration of IO-Link-capable devices into the automation platform and ensures efficient communication between the devices.

The connection elements can each comprise electrical connections such as plug connectors and/or terminals and/or screw connections and/or soldering points and/or contacts, in particular conductor track contacts, or be designed as such. This has the advantage that they enable a fast and secure connection to ensure efficient automation of industrial systems.

Furthermore, within the scope of the invention, it may be provided that the connection elements are arranged at a distance from one another on a housing side of the base body housing in order to receive and hold the further functional module connected thereto in a predefined position on the housing side. This can have the advantage that the additional functional module can be securely held and/or fastened to the housing side of the base body housing—possibly even without additional fastening elements. This enables simple and quick installation of the additional functional module. It is also possible that fastening elements—as part of the connection elements or in addition to the connection elements—are provided in the form of threaded bolts or screws in order to ensure a reliable and robust detachable connection between the base body housing and the further functional module. By using such mechanical fastening elements such as threaded bolts or screws, a high mechanical stability of the connection can be achieved.

Advantageously, the invention may provide that electrical lines, in particular in the form of conductor tracks of at least one printed circuit board of the electronic arrangement, are arranged in the base body housing and electrically connected to the connection arrangement. This can make it possible to provide the main energy flow and/or the auxiliary energy flow and/or the data flow, in particular also for each of the further functional modules (possibly also indirectly through the connected further functional module). This allows the automation platform to be operated for automation, for example by providing motor control as one of the multiple functions. This can have the advantage that a compact and space-saving design of the automation platform is achieved, as the electrical cables are arranged within the base body housing and therefore no additional space requirements arise. The electrical lines can also electrically connect the (first) connection arrangement to a second connection arrangement of the functional module and thus transmit the main energy flow and/or the auxiliary energy flow and/or the data flow from the connected further functional module to a second connected further functional module.

Optionally, it is conceivable that at least one first of the electrical lines is provided to provide the main energy flow and/or at least one second of the electrical lines is provided to provide the auxiliary energy flow and/or at least one or more third of the electrical lines are provided to provide the data flow. In this case, the first(s), the second(s) and/or the third(s) electrical lines may be arranged in different channels of the base body housing and/or separated by partition walls (partitions) and/or formed on different printed circuit boards of the electronic arrangement. This can have the advantage that the different lines can be laid separately from each other in order to avoid interference and disturbances. This increases the reliability and stability of the system. It is also possible for the lines to carry different voltages and currents, which can be better controlled and monitored by separating them and using different circuit boards. This increases the safety of the system and reduces the risk of short circuits and overloads.

Furthermore, it may be advantageous in the context of the invention that the connection arrangement is configured to provide the main energy flow and/or the auxiliary energy flow and/or the data flow between the functional module and the connected further functional module in order to operate the connected further functional module to provide a further one of the plurality of functions, and in particular to provide, through the auxiliary energy flow, the connected further functional module with energy for providing the function. In other words, the main energy flow and/or the auxiliary energy flow may also serve to provide power to at least one of the further functional modules, and possibly not only to an electrical device of the system. It is also possible for data to be exchanged between the functional modules via the data flow. The connection arrangement thus forms a basis for a modular structure of the functional modules to form a flexible automation platform.

In a further possibility, it may be provided that, in addition to the connection arrangement, which as a first connection arrangement provides the electrical connection for the connected further functional module, a second connection arrangement is provided, which may also be arranged on the base body housing in order to provide a second electrical connection for a second of the several further functional modules. The second connection arrangement may also comprise connection elements. The connection elements of the second connection arrangement can also be arranged at a distance from one another on a second housing side of the basic body housing. The second housing side can be opposite the first housing side. In other words, the first and second housing sides can be provided as opposite sides—preferably outer sides—of the base body housing. It is thus possible for the (first) further functional module connected to the first connection arrangement and the second (further) functional module connected to the second connection arrangement to be accommodated and held on opposite sides of the base body housing. If several further functional modules configured in this way are connected to each other with the first and second connection arrangement, a modular series connection of the functional modules can be achieved in this way. This can have the advantage that the overall functionality of the automation platform can be easily expanded by adding additional functional modules

The functional modules of the automation platform can preferably be connected to each other along an axis in a series connection, which follows the connection and preferably plug-in direction of the (first) connection arrangement and in particular also of the (second) connection arrangement or runs parallel to it. This means that the automation platform can be easily extended in a fixed direction by connecting additional functional modules to each other in the direction of the axis. A separate backplane, which connects the functional modules to each other and onto which the functional modules have to be plugged, can therefore be dispensed with. In other words, the backplane is functionally integrated into each of the functional modules. This has the advantage that the automation platform remains space-saving and adaptable without the need for complicated reconfiguration.

Advantageously, in the context of the invention, it may be provided that the connection arrangement, i.e. in particular as a first connection arrangement, and the second connection arrangement are directly connected to at least one printed circuit board of the electronic arrangement in order to provide the main energy flow and/or the auxiliary energy flow and/or the data flow between the first (further) functional module connected to the first connection arrangement and the second (further) functional module connected to the second connection arrangement via the connection arrangements and via the at least one printed circuit board. In other words, the functional module can pass the main energy flow and/or the auxiliary energy flow and/or the data flow from the first connection arrangement to the second connection arrangement. It is also possible that the functional module not only passes through the main energy flow and/or the auxiliary energy flow and/or the data flow, but also diverts it in order to use it itself (e.g. for energy supply or for communication).

It may be advantageous if, in the context of the invention, the main power connection element is designed to provide the main energy flow with an AC voltage of up to 1000 volts and/or a DC voltage of up to 1500 volts and/or with an AC voltage in the range from 70 volts to 1000 volts and/or with a DC voltage in the range from 130 volts to 1500 volts, and preferably with an AC voltage of essentially 400 volts or a DC voltage in the range from 650 V to 700 V, preferably in order to supply at least one electrical device of the industrial plant with energy via the main energy flow, preferably in order to operate a motor. For this purpose, the main energy flow can be provided via the connected further functional module and/or via further of the functional modules for the electrical device, in particular the motor.

It is also conceivable that the main power connection element is designed to provide the main energy flow with an electrical voltage that is at least twice or three times or four times as high as an electrical voltage with which the auxiliary energy flow is provided.

It is also conceivable that the auxiliary power connection element is designed to provide the auxiliary energy flow with an AC voltage of up to 50 volts and/or a DC voltage of up to 120 volts and/or with an AC voltage in the range from 0.01 volts to 50 volts and/or with a DC voltage in the range from 0.01 volts to 120 volts, and preferably with a DC voltage of essentially 24 V or 48 V, preferably in order to provide a power supply for at least one of the further functional modules and/or for communication with at least one of the electrical devices, preferably for a field bus.

It is also conceivable that the data connection element is designed to transmit a data and preferably field bus signal, preferably for communication with at least one of the electrical devices. The data connection element can have several contacts, in particular pins, which enable electrical connections between the functional modules for data exchange. Examples of the contacts are Ground, VCC, Clock, Data, Reset, Enable, Interrupt, Address, Data Bus, Control Bus, Power, Ground, Read, Write, and the like.

For example, it may be provided that the connection arrangement is designed to provide the main energy flow and/or the auxiliary energy flow and/or the data flow between the functional module and the further functional module (connected thereto), in order to provide the main energy flow to at least one of the further functional modules (i.e. in particular also to a further functional module other than the connected further functional module), so that an electrical device of the industrial plant is supplied with energy via this further functional module, and to provide the auxiliary energy and/or data flow to at least one other of the further functional modules, so that the or a further electrical device is controlled via this other further functional module on the basis of the data flow. The control of devices such as motors on the basis of the data flow is provided, for example, in motor control systems, whereby, for example, a speed or rotational speed of the motor is set using a control signal which is transmitted via the data flow.

In a further possibility, it may be provided that the electronic arrangement has at least one printed circuit board, which is arranged inside the base body housing. A plurality of electronic components for providing the at least one function may be arranged on the printed circuit board. Furthermore, a plurality of electrical conductor tracks may be provided on the printed circuit board in order to provide the main energy flow and/or the auxiliary energy flow and/or the data flow, preferably between the first functional module connected to the functional module and a second functional module connected to the functional module.

Furthermore, several electronic components can be provided/arranged on the printed circuit board in order to provide at least one of the several functions, preferably a power supply and/or control function for at least one electrical device of the industrial system. For this purpose, one or more device connections for the at least one electrical device can be arranged on the base body housing and/or electrically connected to the printed circuit board. This preferably serves to provide the main energy flow and/or the auxiliary energy flow and/or the data flow and/or the energy supply and/or control function for the at least one electrical device via the device connections.

A further advantage within the scope of the invention can be achieved if the connection arrangement is arranged on a housing connection surface of the base body housing. Furthermore, at least one receptacle for a fastening element can be provided in the basic body housing in order to connect the functional module to the further functional module. In this case, it may be provided that the receptacle is inclined relative to the housing connection surface. In other words, the receptacle can be mounted at an angle to the housing connection surface, for example at an angle of less than 90° or less than 70° or in the range from 10° to 80° in relation to a longitudinal axis of the receptacle and the plane defined by the housing connection surface.

The functional modules can be pulled together and connected to each other using the fastening described, in particular by means of an angled screw connection. Each basic body housing also has optional straight threaded holes on both sides for attaching a cover after each module to complete the resulting system. To connect the individual functional modules to each other, plugs and sockets, for example, can be used as fastening elements and receptacles, which are closed at the end by the covers.

It is also advantageous if the (first and/or second) connection arrangement is arranged on a (respective first and/or second) housing connection surface of the base body housing. At least or exactly one sealing means, also referred to as sealant, can be arranged on the housing connection surface, in particular in order to be pressed through the connection of the further functional module and reliably seal the connection in this way. In this way, moisture or dirt can be prevented from entering the basic body housing. It is also possible for the sealant/sealing means to be made of an elastic material in order to ensure better adaptation to the housing connection surface. This makes it possible to achieve a higher level of tightness, which is particularly advantageous for applications in damp or dusty environments. It is also possible for the sealant to be in the form of sealing tapes or sealing cords. These can be placed around the connection surface and their shape ensures a reliable seal. Alternatively, the sealant can also be in the form of sealing pastes or sprays that are applied directly to the connection surface. This form of sealant can be applied particularly easily and quickly, but the further manufacturing step in a method according to the invention is conceivable in that the sealing paste or spray must be allowed to cure completely in order to ensure a reliable seal.

Another possible design of the sealing means (sealant) is a lamellar seal, which can have the advantage that it can adapt flexibly to the connection surface and thus ensure a reliable seal even in the event of unevenness. The lamellar seal can be made of an elastic material such as silicone and produced in the form of strips or tapes. These can then be placed around the connection surface and pressed together by the connection of the additional functional module, creating a reliable seal.

Another way to improve the tightness of the connection is to provide the connection arrangement with an additional securing element that additionally stabilizes the connection between the two functional modules and thus prevents the connection from loosening or shifting. This can be a screw or a clamp, for example, which firmly connects the two functional modules.

Furthermore, within the scope of the invention, it may be provided that at least one fastening means is provided on the base body housing in order to fasten a cover with the functional modules, which closes the functional modules that are connected to one another in a modular manner. This can have the advantage that the functional modules can be stored safely and protected from external influences. In addition, easy handling and quick replacement of the functional modules can be ensured by detachably attaching the cover to the base body housing. It is also possible that the fastening means enable a positive connection between the lid and the base body housing to ensure additional stability and safety.

Advantageously, the invention may provide that a heat sink is provided on an underside of the base body housing in order to provide heat dissipation for the electronic arrangement. This can have the advantage that overheating of the electronic arrangement is avoided, which increases the service life of the components and improves the reliability of the entire arrangement. It is also possible for the heat sink to be made of a material with high thermal conductivity in order to ensure effective heat dissipation. For example, the heat sink is made of aluminum or copper and attached to the base body housing by fastening means such as screws. By using such a heat sink, the arrangement can be operated reliably even at high temperatures. The heat sink can be arranged on the underside of the functional module or base body housing opposite the cover. In contrast, the connection arrangement, and possibly also the second connection arrangement, can be provided on the side surfaces of the basic body housing.

Another object of the invention is an automation platform comprising a functional module according to the invention and the further functional modules. The automation platform according to the invention thus has the same advantages as those described in detail with reference to a functional module according to the invention For example, at least or exactly one or two or three or four or up to 10 further functional modules can be provided and, if necessary, connected to one another in series.

It is also optionally conceivable that the functional module has the connection arrangement and in particular a second connection arrangement, and the respective further functional modules also have at least one (or two opposite) further connection arrangement(s) in order to connect the functional modules to each other in series and to provide the main energy flow and/or the auxiliary energy flow and/or the data flow between the functional modules. This enables a compact arrangement and expansion of the automation platform.

The automation platform can be used for a variety of automation tasks and related automation functions. For example, functional modules can be provided for feeding in a main and/or auxiliary energy flow as a first function, and/or for feeding in an auxiliary energy and/or data flow (e.g. as a fieldbus and/or network and/or Internet interface) as a further function, and/or for motor control as a further function, and/or for data processing as a further function, e.g. by an industrial PC functional module, and/or for a power supply for electrical devices of the industrial plant as a further function, and/or for energy buffering (i.e. intermediate storage of energy) for the energy supply of at least one of the functional modules, such as the industrial PC functional module, as a further function, and/or for the provision of IO-Link communication for the electrical devices as a further function, e.g. by an IO-Link master functional module, and/or for a fieldbus connection by a fieldbus interface such as an Ethernet switch as a further function and/or for a cloud connection by an Internet interface as a further function and/or for a sensor connection as a further function, and/or for the creation of a digital twin, e.g. for project planning, as a further function, and/or for monitoring the automation and/or the industrial plant by means of an app, in particular by means of a wireless interface, as a further function, and/or for a predictive maintenance application, e.g. by means of a corresponding data processing unit, as a further function.

At least one of the functional modules of the automation platform can be designed for cloud connection. For this purpose, the functional module can have an Internet interface, which can be implemented on the hardware side as an Ethernet interface and/or on the software side as a REST API or a SOAP interface. This allows the decentralized automation of the industrial plant to be supported by transferring the data of the plant to the cloud, particularly in real time. This enables, for example, remote monitoring and control of the system, as well as analysis and evaluation of the data. In addition, updates and maintenance of the system can be carried out remotely, which leads to greater efficiency and availability of the system.

Furthermore, at least one of the functional modules of the automation platform can be provided for sensor and/or sensor-based connection. In other words, the functional module can be used to integrate sensors of the industrial plant into an automated production line. In this case, the functional module for sensor connection can have a sensor interface such as an IO-Link interface to enable communication between the sensor and a control system.

Furthermore, at least one of the functional modules of the automation platform can be provided for creating a digital twin, e.g. for project planning. For this purpose, the functional module can be supplemented by a corresponding software solution. By using sensor data and other real-time data, possibly received from the cloud, the digital twin can represent an exact copy of the real object or industrial plant. This makes it possible to run various scenarios and simulations to predict and optimize the performance and behaviour of the real object or plant.

Furthermore, at least one of the functional modules of the automation platform can be provided for monitoring the automation and/or the industrial plant by means of an app. For this purpose, the functional module can be equipped with an interface for wireless communication. The app can then be installed and used on a mobile device. The app can be used to monitor and analyze the relevant data of the automation and/or the industrial plant in real time. This enables the user to react quickly to potential problems and operate the system more effectively.

Furthermore, at least one of the functional modules of the automation platform can be provided for a predictive maintenance application, e.g. by a corresponding data processing unit. In other words, it is possible for the functional module to be supplemented by a data processing unit for predictive maintenance applications. For this purpose, the functional module can be equipped with at least one interface for sensor-based data collection and forwarding to the data processing unit. This enables the data processing unit to analyze the data and make predictions about potential failures or maintenance requirements.

Furthermore, at least one of the functional modules can have a communication and preferably radio interface, e.g. a W-LAN and/or 5G and/or Bluetooth interface.

In addition to their respective functions, the functional modules can also provide an electrical connection platform in which connection lines are provided to provide a main power (such as 400V/16A), auxiliary power (24V/48V) and data flow. The connection of the functional modules allows existing solutions to be adapted and additional functional modules to be added. For example, one of the functional modules of the automation platform can be designed as a safety controller, which enables the main energy flow to be fed in via a main switch. Furthermore, one of the functional modules of the automation platform can be designed as a power supply unit for the electronics, which provides the auxiliary energy flow with 24 V, for example. A power supply for drive technology can also be provided as an auxiliary power supply, e.g. with 48 V. MQ15 DC connections and a hybrid cable can be used to supply the drives, which also supplies the actuators and emergency shutdown via an STO signal.

Furthermore, at least one of the functional modules of the automation platform can be designed as an industrial PC. The industrial PC, also referred to as a controller, may comprise a multi-core CPU. Communication takes place, for example, via various channels such as W-LAN, 5G and Bluetooth as well as OPC-UA (Open Platform Communications Unified Architecture) and MQTT (Message Queuing Telemetry Transport). An 8 Ah Li-Ion battery can be provided to buffer the industrial PC to ensure fast start-up times from sleep mode. Furthermore, an IO-Link master, e.g. with 8-fold connection option, as well as an Ethercat Safety with IO and 16/4 connection can be provided. It is also possible to configure one of the functional modules as an 8-way single pair Ethernet switch.

It is possible for the automation platform to consist of only the functional modules without a separate backplane. Therefore, the functional modules themselves can have the connections via the connection elements in order to be mechanically and electrically connected to each other. In other words, the functional modules for the modular structure of the automation platform can themselves have the connection lines and connections that are usually provided on a separate backplane. This makes it possible to provide an automation platform that can be assembled as required and bring the automation components into the field in a decentralized manner. In this way, the automation platform can be used for decentralized automation with a modular system and at least partially replace a control cabinet, as is usually used for central topologies of an electrical system, in particular an automation system. In particular, the electrical connection concept of the automation platform offers the possibility of providing separate lines for the different voltages and data connections. A fieldbus connection is suitable for data transmission, for example. The integration of decentralized servo drives enables reliable voltage, signal and data management directly in the field. This means that all automation functions can be implemented completely decentrally and without a control cabinet. The automation platform can therefore serve as a decentralized automation system with a modular design and at least partially replace a control cabinet. There is no need for complex installation, set-up times and sources of error are eliminated and maintenance can optionally be adapted to the production cycles using predictive maintenance.

In particular, the automation platform is a system without a separate backplane and preferably consists only of the functional modules.

Another object of the invention is a method for providing a decentralized automation platform, in which a functional module is connected to several further functional modules in a modular manner, in particular in order to provide several functions for the automation of an industrial plant in a modular manner.

The method according to the invention may comprise, according to a first method step: providing an electronic arrangement for performing at least one of the plurality of functions.

Furthermore, the method according to the invention can have as a further method step Providing a base body with a base body housing in which the electronic arrangement is arranged.

The method according to the invention may further comprise as a further method step Providing a connection arrangement, which is arranged on the base body housing and/or a housing connected thereto and/or is electrically connected to the electronics arrangement in order to provide an electrical connection for one of the plurality of further functional modules. The connection arrangement can provide a main energy flow and/or an auxiliary energy flow and/or a data flow between the functional module and the connected further functional module in order to operate the automation platform for automating the industrial plant. For this purpose, the connection arrangement can also comprise the following connection elements:
a main power connection element to provide the main energy flow for the further functional module connected to it,
an auxiliary power connection element for providing the auxiliary energy flow, with a lower electrical voltage than the main energy flow, for the further functional module connected to it,
a data connection element to provide the data flow for the further functional module connected to it.

The method according to the invention thus has the same advantages as those described in detail with reference to a functional module according to the invention.

The automation platform can be decentralized in that it provides automation functions for the system, particularly plant, with one or more other decentralized automation platforms. The one or more further decentralized automation platforms can also each be designed as an automation platform according to the invention. The automation platforms can accordingly provide partial automation functions that enable the automation of the system in a complementary manner. The partial automation functions include, for example, control and/or regulation of variables such as pressure, flow or temperature and/or monitoring of process parameters and/or control and/or evaluation of actuators and sensors.

It is possible that the individual different partial automation functions are provided by functional modules designed for this purpose. In this way, partial automation functions can be supplemented and combined on a modular basis in an automation platform. The functional modules include, for example, a power supply module, such as a power supply unit, and/or a fieldbus module and/or a safety module for monitoring and safeguarding processes and/or a motor control module and/or an industrial PC that can perform control tasks. In addition, pneumatic and/or hydraulic modules can also be provided as functional modules, for example to control movements and forces. These modules can, for example, be designed to control cylinders, valves and/or pumps These functional modules can also include cylinders, valves and/or pumps. By combining electronic and pneumatic/hydraulic elements, complex and precise control tasks can be realized in various application areas, such as automation technology.

It is also conceivable that the automation platforms are connected to a higher-level controller (central controller), e.g. via a fieldbus system. However, the decentralized automation platforms can at least partially replace the function of a central control cabinet. For this purpose, the automation platform can be arranged in the field of the system, e.g. in the vicinity of actuators and sensors. This can have the advantage of achieving a high degree of flexibility and scalability of the automation, as further decentralized automation platforms can be added easily to provide additional automation functions. It is also possible that the decentralized design of the automation platforms makes the automation easier to maintain, more robust and fail-safe, as failures of individual components can be compensated for by other decentralized automation platforms. This ensures a high level of automation availability.

Another object of the invention can optionally be a system for an industrial system and/or an industrial plant which has at least two or at least four or at least six automation platforms. The respective automation platform can be decentralized in that it provides automation functions and preferably partial automation functions for the industrial plant together with the respective other automation platform or platforms. The respective automation platforms can be designed as automation platforms according to the invention.

The automation platforms can optionally each provide partial automation functions that complement each other (i.e. in relation to the joint provision of the partial automation functions by all the automation platforms) and/or enable the automation of the system in a complementary manner. The partial automation functions include, for example, control and/or regulation of variables such as pressure, flow or temperature and/or monitoring of process parameters and/or control and/or evaluation of actuators and sensors.

A system with decentralized automation platforms can also be protected.

### BRIEF DESCRIPTION OF THE DRAWINGS

Further advantages, features and details of the invention are apparent from the following description, in which embodiments of the invention are described in detail with reference to the drawings. The features mentioned in the claims and in the description may each be essential to the invention individually or in any combination. It shows:

FIG. 1 a perspective view of a functional module according to embodiments of the invention.

FIG. 2 a side view of a functional module according to embodiments of the invention.

FIG. 3 a sectional view of an automation platform according to embodiments of the invention.

FIG. 4 a schematic connection diagram of an automation platform according to embodiments of the invention.

FIG. 5 schematic of a method according to embodiments of the invention.

In the above cited figures, the identical reference symbols are used for the same technical features, even for different embodiments.

### DETAILED DESCRIPTION

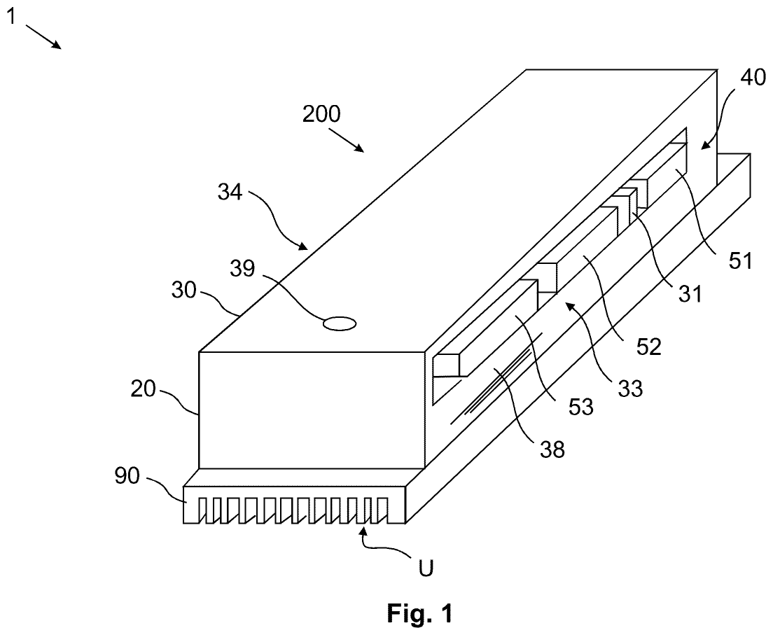

According to embodiments of the invention, FIG. 1 illustrates a functional module 200 for forming a decentralized automation platform 1, in which the functional module 200 can be modularly connected to several further functional modules 201. In this way, several functions for the automation of an industrial system can be expanded in a modular fashion

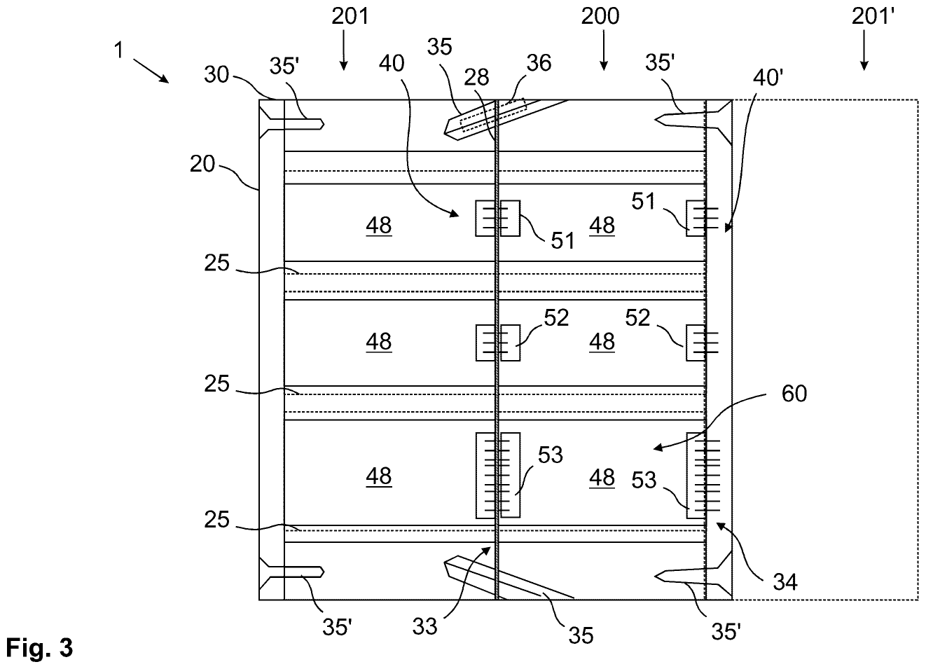

The functional module 200 can be designed as a portable component that is manually connected to further functional modules 201 for assembly. A base body 20 is therefore provided, which has a base body housing 30. The base body housing can be essentially rectangular in shape, so that the multiple functional modules 200, 201 can be simply plugged together in a space-saving and easy-to-handle manner. For safe assembly, the base body housing 30 can have an electrically insulating plastic. An electronic arrangement 60 illustrated in FIG. 3 can be arranged in the base body. The electronic arrangement 60 serves in particular to provide at least one of the several functions. Depending on the functional module, this function and thus also the electronic arrangement 60 may differ. For example, functional modules 200, 201 can be provided for:
a supply of a main and/or auxiliary energy flow as a first function, and/or
a supply of an auxiliary and/or data flow (e.g. as a fieldbus interface) as a further function, and/or
motor control as a further function, and/or
data processing as a further function, e.g. by an industrial PC functional module, and/or
a power supply for electrical devices of the industrial plant as a further function, and/or
energy buffering (i.e. intermediate storage of energy) for supplying energy to at least one of the functional modules, such as the industrial PC functional module, as a further function, and/or
provision of IO-Link communication for the electrical devices as a further function, e.g. by an IO-Link master functional module, and/or
a fieldbus interface such as an Ethernet switch as an additional function.

It can be seen that by selecting several of these functional modules 200,201, an automation platform 1 with versatile functionality can be constructed in a modular and flexible manner and easily adapted to specific automation tasks of the industrial plant.

In order to enable the automation platform 1 to be assembled, according to embodiments of the invention it is provided that the functional modules 200, 201 are connected to one another and preferably plugged together. For this purpose, a connection arrangement 40 shown in FIG. 1 is provided, which is arranged on the base body housing 30 in order to provide an electrical connection for one of the several further functional modules 201. Via the electrical connection, for example, the main energy and/or auxiliary energy and/or data energy flow can be electrically transmitted to the further functional module 201 connected thereto. In other words, the connection arrangement 40 can be designed to provide a main energy flow, an auxiliary energy flow and a data flow between the functional module 200 and the connected further functional module 201 in order to operate the automation platform 1 for automating the industrial plant.

The electrical voltages that are provided at the connection arrangement 40 in order to enable the main energy, auxiliary energy and/or data flow do not necessarily have to be used by the connected functional module 201. An industrial PC, for example, does not necessarily require the main energy flow. However, it is advantageous if the connected functional module 201 nevertheless forwards the main energy flow, auxiliary energy flow and/or data flow in order to make these available to the further functional modules 201. This ensures a modular expansion of the automation platform 1.

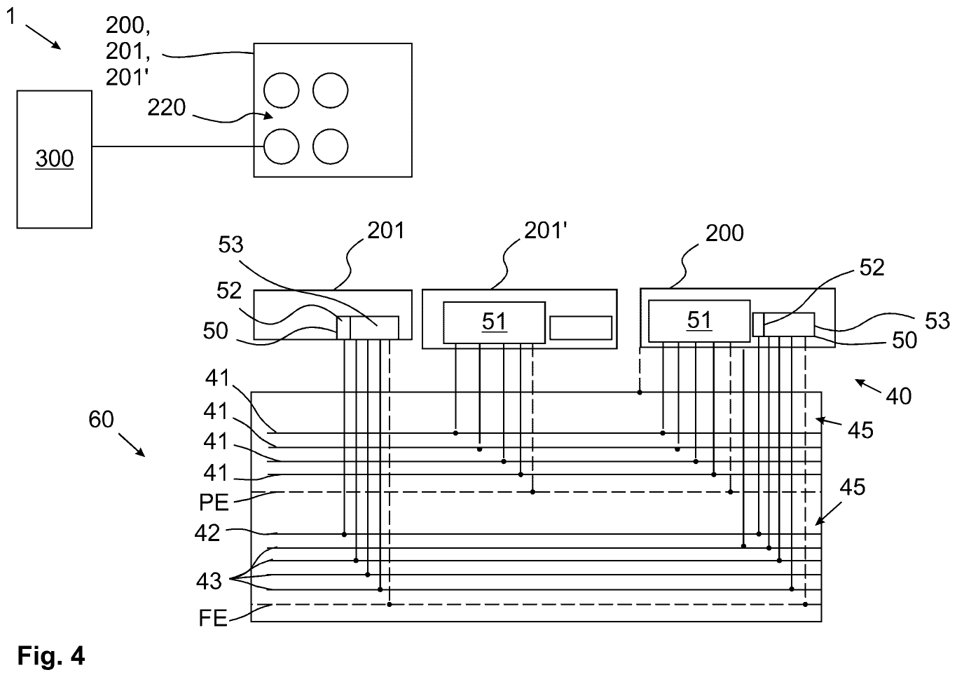

In detail, the connection arrangement 40 can comprise the following connection elements 50 illustrated in FIGS. 1-4: a main power connection element 51 for providing the main energy flow for the further functional module 201 connected thereto, an auxiliary power connection element 52 for providing the auxiliary energy flow, with a lower electrical voltage than the main energy flow, for the further functional module 201 connected thereto, and a data connection element 53 for providing the data flow for the further functional module 201 connected thereto. A possible electrical connection configuration of these connection elements 50 is shown in FIG. 4 in a schematic circuit diagram. It can also be seen therein that not all functional modules 200, 201 of the automation platform 1 must have each of these connection elements 51-53. However, it is advantageous if those functional modules 200,201 to which two functional modules 200,201 are connected also have all connection elements 51-53 for forwarding the main energy, auxiliary energy and data flow-in order to ensure smooth forwarding of the main energy, auxiliary energy and data flow in this cascade.

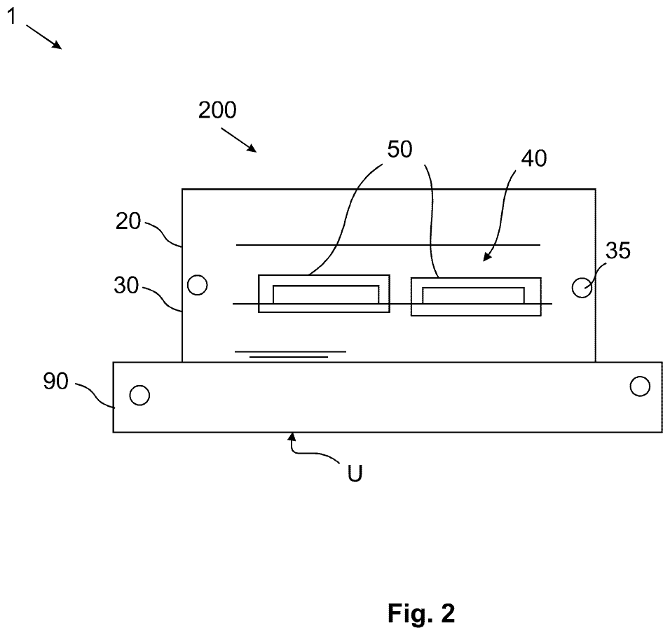

In FIGS. 1 and 2, it can be seen that the connection elements 50 can be arranged at a distance from one another on the housing side 33 of the base body housing 30 in order to receive and hold the further functional module 201 connected thereto in a predefined position on the housing side 33. In addition to the connection arrangement 40, which as a first connection arrangement 40 provides the electrical connection for the connected further functional module 201, a second connection arrangement 40′ shown schematically in FIG. 3 can be provided, which is arranged on the base body housing 30. The second connection arrangement 40′ can provide a second electrical connection for a second functional module 201′ (not shown with further details, but possibly identical in construction to the functional module 201 or 200 with respect to the connection arrangement 40) of the plurality of further functional modules 201. The second connection arrangement 40′ can also comprise connection elements 50 that are identical in construction to the first connection arrangement 40. Accordingly, the connection elements 50 of the second connection arrangement 40′ can also be arranged at a distance from one another, but on a second housing side 34 of the base body housing 30. It is advantageous if the second housing side 34 is opposite the first housing side 33, in order to receive and hold the further first functional module 201 connected to the first connection arrangement 40 and the second functional module 201′ connected to the second connection arrangement 40′ on opposite sides of the base body housing 30.

Within the base body housing 30, onward transmission can be enabled by electrical lines 45. The electrical lines 45 are provided, for example, in the form of conductor paths 45 of at least one printed circuit board 48 of the electronic arrangement 60 (see FIG. 3, wherein the lines 45 can extend, for example, as conductor paths between the similar connection elements 51 or 52 or 53 of the first housing side 33 and the second housing side 34). The conductors 45 may be arranged in the base body housing 30 and electrically connected to the connection arrangement 40 in order to provide the main energy flow and/or the auxiliary energy flow and/or the data flow. The connection arrangement 40 and the second connection arrangement 40′ can be directly connected to at least one printed circuit board 48 of the electronic arrangement 60 in order to provide the main energy flow, the auxiliary energy flow and the data flow between the first functional module 201 connected to the first connection arrangement 40 and the second functional module 201′ connected to the second connection arrangement 40′ via the connection arrangements and via the at least one printed circuit board 48.

The electrical lines 45 can be provided as shown in FIGS. 3 and 4 as follows: At least one first line 41 is used for the main power supply, at least one second line 42 is used for the auxiliary power supply and at least one third line 43 is used for data transmission. According to embodiments of the invention, these lines 41, 42, 43 are arranged in different channels 25 of the base body housing 30 (see FIG. 3), in particular implemented on different printed circuit boards 48 of the electronic arrangement 60 and/or separated by partition walls 31 (see FIG. 1).

The main power connection element 51 shown in FIG. 3 can be designed to provide the main energy flow in order to supply at least one electrical device 300 of the industrial system shown in FIG. 4 with energy via the main energy flow. For example, a motor can be operated, with the main energy flow being provided for the electrical device 300 or the motor via the connected further functional module 201 and/or via further of the functional modules 201′.

The auxiliary power connection element 52 can be designed to provide the auxiliary energy flow in order to provide a power supply for at least one of the further functional modules 201 and/or for communication with at least one of the electrical devices 300, preferably for a fieldbus. Furthermore, the data connection element 53 can be designed to transmit a data signal and preferably a fieldbus signal, preferably for communication with at least one of the electrical devices 300.

The electronic arrangement 60 shown schematically in FIG. 3 may provide at least one of the plurality of functions, preferably a power supply and/or control function for at least one electrical device 300 of the industrial system. To this end, one or more device connections 220 shown in FIG. 4 for the at least one electrical device 300 may also be arranged on the base body housing 30 and/or electrically connected to the printed circuit board 48, preferably to provide the main energy flow and/or the auxiliary energy flow and/or the data flow and/or the power supply and/or control function for the at least one electrical device 300 via the device connections 220. Such device connections 220 may also optionally be provided on the further functional modules 201,201′.

FIG. 3 further illustrates a mechanical fastening solution according to embodiments of the invention. Here, at least one receptacle 35 for a fastening element 36 can be provided in the base body housing 30 in order to connect the functional module 200 to the further functional module 201. Optionally, further receptacles 35′ may also be provided for this purpose. It can be seen that the receptacle 35 can be inclined. For example, the receptacle 35 may not extend vertically into the base body housing 30 with respect to a housing connection surface 38 illustrated in FIG. 1, but may be inclined with respect to the housing connection surface 38, i.e. have an angle not equal to 90 degrees.

Furthermore, FIG. 3 schematically shows that at least or exactly one sealing means 28 is provided on the housing connection surface 38 in order to be pressed through the connection of the further functional module 201 and to seal the connection. This can have the advantage that the ingress of moisture and dust into the housing of the functional module is prevented. Possible concrete designs of the sealant 28 can be a lamellar seal, a silicone sealant, a sealing tape or a prefabricated seal. With regard to the geometry of the sealant 28, a flat layer or an annular seal or an essentially rectangular-shaped seal is conceivable.

According to FIG. 1, at least one fastening means 39 can be provided on the base body housing 30 in order to fasten a cover, which is not explicitly shown, with the functional modules 200, 201, which closes the functional modules 200, 201 that are modularly connected to one another. Furthermore, a heat sink 90 can be provided on an underside U of the base body housing 30 in order to provide heat dissipation for the electronic arrangement 60. In the example shown, the heat sink 90 has several fins that are designed for better heat dissipation. The heat sink 90 is made of aluminum, for example.

FIGS. 1 to 4 also show at least parts of an automation platform 10 comprising a functional module 200 according to embodiments of the invention as well as the further functional modules 201.

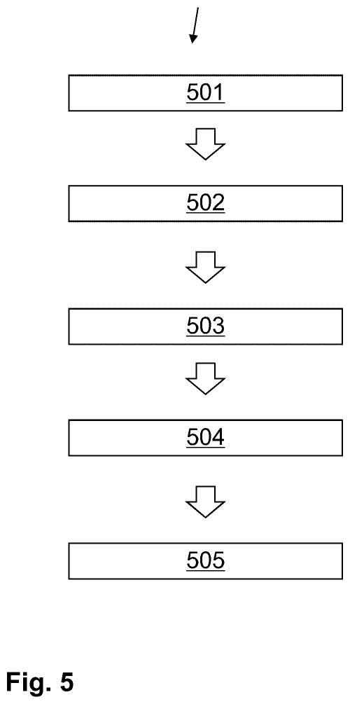

In FIG. 5, a method 500 for providing a decentralized automation platform 1 according to embodiments of the invention is shown. The method steps 501-105 may be provided for each of the functional modules 200, 201, 201′ of the automation platform 1:

According to a first method step 501, an electronic arrangement 60 for performing at least one of the plurality of functions is provided. Furthermore, according to a second method step 502, a base body 20 with a base body housing 30 is provided, in which the electronic arrangement 60 is arranged. According to a third method step 503, a connection arrangement 40 is provided, which is arranged on the base body housing 30 in order to provide an electrical connection for one of the plurality of further functional modules 201. The connection arrangement 40 can provide a main energy flow, an auxiliary energy flow and a data flow between the functional module 200 and the connected further functional module 201 in order to operate the automation platform 1 for automating the industrial plant. According to a fourth method step 504, a plurality of connection elements 50 may be provided for the connection arrangement 40, comprising a main power connection element 51, an auxiliary power connection element 52 and a data connection element 53. Finally, according to a fifth method step 505, the automation platform 1 may be provided by connecting a plurality of functional modules 200, 201, 201′ to each other.

The foregoing explanation of the embodiments describes the present invention solely by way of examples. Of course, individual features of the embodiments can be freely combined with one another, provided that this is technically feasible, without departing from the scope of the present invention.

### LIST OF REFERENCE SYMBOLS

1 Automation platform
20 Base body
25 Channels
28 Sealant
30 Base body housing
31 Partition wall
33 (first) housing side
34 Second housing side
35 Receptacle
36 Fastening element
38 Housing connection surface
39 Fasteners
40 Connection arrangement
41 Main power lines
42 Auxiliary power lines
43 Data lines
45 Cables
48 Printed circuit board
50 Connection elements
51 Main power connection element
52 Power supply connection element
53 Data link element
60 Electronics arrangement
90 Heat sink
200 Functional modules
201 Further functional modules
220 Device connections
300 Electrical devices
35′ further receptacle
40′ Further connection arrangement
500 Method
201′ second functional module
U Underside

1. Functional module for forming a decentralized automation platform, in which the functional module is modularly connected to a plurality of further functional modules in order to provide a plurality of functions for the automation of an industrial plant in a modularly expandable manner, comprising:
an electronic arrangement for providing at least one of the plurality of functions,
a base body with a base body housing in which the electronic arrangement is arranged,
a connection arrangement arranged on the base body housing and/or electrically connected to the electronic arrangement to provide an electrical connection for one of the plurality of further functional modules,
wherein the connection arrangement is designed to provide a main energy flow, an auxiliary energy flow and a data flow between the functional module and the connected further functional module in order to operate the automation platform for the automation of the industrial plant, wherein the connection arrangement comprises the following connection elements for this purpose:
a main power connection element for providing the main energy flow for the further functional module connected thereto,
an auxiliary power connection element for providing the auxiliary energy flow, with a lower electrical voltage than the main energy flow, for the further functional module connected thereto,
a data connection element for providing the data flow for the further functional module connected thereto.

2. Functional module according to claim 1,
characterized in that
in that the connection elements are arranged at a distance from one another on a housing side of the basic body housing in order to receive and hold the further functional module connected thereto in a predefined position on the housing side.

3. Functional module according to claim 1,
characterized in that
in that electrical lines are arranged in the base body housing and are electrically connected to the connection arrangement in order to provide the main energy flow and/or the auxiliary energy flow and/or the data flow.

4. Functional module according to claim 1,
characterized in that
in that the connection arrangement is designed to provide the main energy flow, the auxiliary energy flow and the data flow between the functional module and the connected further functional module in order to operate the connected further functional module to provide a further one of the plurality of functions.

5. Functional module according to claim 1,
characterized in that
in that in addition to the connection arrangement, which as a first connection arrangement provides the electrical connection for the connected further functional module, a second connection arrangement is provided, which is arranged on the basic body housing in order to provide a second electrical connection for a second of the plurality of further functional modules, the second connection arrangement likewise comprising connection elements, the connection elements of the second connection arrangement being arranged at a distance from one another on a second housing side of the base body housing, which is opposite the first housing side, in order to receive and hold the further (first) functional module connected to the first connection arrangement and the second functional module connected to the second connection arrangement on opposite sides of the base body housing.

6. Functional module according to claim 1,
characterized in that
in that the main power connection element is designed to provide the main energy flow with an AC voltage of up to 1000 volts and/or a DC voltage of up to 1500 volts and/or with an AC voltage in the range from 70 volts to 1000 volts and/or with a DC voltage in the range from 130 volts to 1500 volts,
and/or in that the auxiliary power connection element is designed to provide the auxiliary energy flow with an AC voltage of up to 50 volts and/or a DC voltage of up to 120 volts and/or with an AC voltage in the range from 0.01 volts to 50 volts and/or with a DC voltage in the range from 0.01 volts to 120 volts.

7. Functional module according to claim 1,
characterized in that
in that the connection arrangement is designed to provide the main energy flow, the auxiliary energy flow and the data flow between the functional module and the connected further functional module in order to provide the main energy flow to at least one of the further functional modules, so that an electrical device of the industrial plant is supplied with energy via this further functional module, and to provide the auxiliary energy flow and/or data flow to at least one other of the further functional modules so that the or another electrical device is controlled via this other further functional module on the basis of the data flow.

8. Functional module according to claim 1,
characterized in that
in that the electronic arrangement has at least one printed circuit board which is arranged within the basic body housing, a plurality of electrical conductor tracks being provided on the printed circuit board in order to provide the main energy flow and/or the auxiliary energy flow and/or the data flow, and a plurality of electronic components being arranged on the printed circuit board in order to provide the at least one of the plurality of functions.

9. Functional module according to claim 1,
characterized in that
in that the connection arrangement is arranged on a housing connection surface of the basic body housing, at least one receptacle for a fastening element being provided in the basic body housing in order to connect the functional module to the further functional module, the receptacle being inclined with respect to the housing connection surface.

10. Functional module according to claim 1,
characterized in that
in that the connection arrangement is arranged on a housing connection surface of the basic body housing, at least or precisely one sealing means being arranged on the housing connection surface in order to be pressed through the connection of the further functional module and to seal the connection.

11. Functional module according to claim 1,
characterized in that
in that at least one fastening means is provided on the basic body housing in order to fasten a cover with the functional modules, which closes the functional modules connected to one another in a modular manner.

12. Functional module according to claim 1,
characterized in that
in that a heat sink is provided on an underside (U) of the base body housing in order to provide heat dissipation for the electronic arrangement.

13. An automation platform, comprising:
a functional module modularly connected to a plurality of further functional modules in order to provide a plurality of functions for the automation of an industrial plant in a modularly expandable manner, the functional module comprising:
an electronic arrangement for providing at least one of the plurality of functions,
a base body with a base body housing in which the electronic arrangement is arranged,
a connection arrangement arranged on the base body housing and/or electrically connected to the electronic arrangement to provide an electrical connection for one of the plurality of further functional modules,
wherein the connection arrangement is designed to provide a main energy flow, an auxiliary energy flow and a data flow between the functional module and the connected further functional module in order to operate the automation platform for the automation of the industrial plant, wherein the connection arrangement comprises the following connection elements for this purpose:
a main power connection element for providing the main energy flow for the further functional module connected thereto,
an auxiliary power connection element for providing the auxiliary energy flow, with a lower electrical voltage than the main energy flow, for the further functional module connected thereto,
a data connection element for providing the data flow for the further functional module connected thereto.

14. Automation platform according to claim 13,
characterized in that
in that the functional module has the connection arrangement, and the respective further functional modules also have at least one further connection arrangement in order to connect the functional modules to one another in series and in order to provide the main energy flow, the auxiliary energy flow and the data flow between the functional modules.

15. Method for providing a decentralized automation platform, in which a functional module is connected in a modular manner to a plurality of further functional modules in order to provide a plurality of functions for the automation of an industrial plant in a modular manner, wherein the following steps are provided:
providing an electronic arrangement for performing at least one of the plurality of functions,
providing a base body with a base body housing in which the electronic arrangement is arranged,
providing a connection arrangement which is arranged on the base body housing and/or is electrically connected to the electronic arrangement in order to provide an electrical connection for one of the plurality of further functional modules,
wherein the connection arrangement provides a main energy flow, an auxiliary energy flow and a data flow between the functional module and the connected further functional module in order to operate the automation platform for the automation of the industrial plant, wherein the connection arrangement comprises the following connection elements for this purpose:
a main power connection element for providing the main energy flow for the further functional module connected thereto,
an auxiliary power connection element for providing the auxiliary energy flow, with a lower electrical voltage than the main energy flow, for the further functional module connected thereto,
a data connection element for providing the data flow for the further functional module connected thereto.

16. The functional module of claim 3 wherein at least one of:
(a) wherein the electrical lines comprise conductor tracks of at least one printed circuit board of the electronic arrangement;
(b) wherein the electrical lines are arranged in the base body housing and are electrically connected to the connection arrangement in order to provide the main energy flow and/or the auxiliary energy flow and/or the data flow for each of the further functional modules and thereby to operate the automation platform for automation;
(c) wherein to operate the automation platform for automation comprises provision of motor control as one of the plurality of functions; and/or
(d) wherein to operate the automation platform for automation comprises providing in that at least one first of the electrical lines is provided for providing the main energy flow, at least one second of the electrical lines is provided for providing the auxiliary energy flow and at least third of the electrical lines are provided for providing the data flow, the first, the second and the third electrical lines being arranged in different channels of the base body housing and/or being separated by partitions and/or being formed on different printed circuit boards of the electronic arrangement.

17. The functional module of claim 4 wherein provision of the further one of the plurality of functions comprises supplying the connected further functional module with energy for providing the function by means of the auxiliary energy flow.

18. The functional module of claim 5 wherein the first connection arrangement and the second connection arrangement are directly connected to at least one printed circuit board of the electronic arrangement in order to provide the main energy flow, the auxiliary energy flow and the data flow between the first functional module connected to the first connection arrangement and the second functional module connected to the second connection arrangement via the connection arrangements and via the at least one printed circuit board.

19. The functional module of claim 6 wherein at least one of:
(a) wherein, for the main energy flow, the AC voltage is essentially 400 volts or the DC voltage is in the range from 650 V to 700 V;
(b) wherein the main power connection element is designed to provide the main energy flow to supply at least one electrical device of the industrial plant with energy via the main energy flow;
(c) wherein the main power connection element is designed to provide the main energy flow to operate a motor;
(d) wherein the main power connection element is designed to provide the main energy flow via the connected further functional module and/or via further of the functional modules for the electrical device;
(e) wherein, for the auxiliary energy flow, the DC voltage is essentially 24 V or 48 V;
(f) wherein the auxiliary power connection element is designed to provide a power supply for at least one of the further functional modules and/or for communication with at least one of the electrical devices;
(g) wherein the auxiliary power connection element is designed to provide the auxiliary energy flow to operate a field bus; and/or
(h) wherein data connection element is designed to transmit field bus signal for communication with at least one of the electrical devices.

20. The functional module of claim 8 wherein at least one of:
(a) wherein the main energy flow and/or the auxiliary energy flow and/or the data flow is between the first functional module connected to the functional module and a second functional module connected to the functional module;
(b) wherein provision of the at least one of the plurality of functions comprises a power supply and/or control function for at least one electrical device of the industrial plant, one or more device connections for the at least one electrical device being arranged on the base body housing and/or electrically connected to the printed circuit board for this purpose; and/or
(c) wherein provision of the at least one of the plurality of functions comprises providing the main energy flow and/or the auxiliary energy flow and/or the data flow and/or the power supply and/or control function for the at least one electrical device via the device connections.
